(19) United States
(12) Patent Application Publication
(10) Pub. No.: US 2008/0236493 A1
(43) Pub. Date: Oct. 2, 2008

(54) PLASMA PROCESSING APPARATUS

(75) Inventor: Yosuke SAKAO, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/055,945

(22) Filed: Mar. 26, 2008

Related U.S. Application Data
(60) Provisional application No. 60/940,100, filed on May 25, 2007.

(30) Foreign Application Priority Data
Mar. 27, 2007 (JP) 2007-082559

(51) Int. Cl. C23C 16/505

(52) U.S. Cl. 118/723 I

(57) ABSTRACT

A plasma processing apparatus performs a plasma processing on a substrate to be processed by generating plasma between a first electrode and a second electrode disposed to face each other in a processing chamber by applying a radio frequency power to the first electrode from a radio frequency power supply connected to the first electrode. The plasma processing apparatus includes a dielectric body disposed near the first electrode and a conductor provided in the dielectric body. Further, a radio frequency leakage line is connected to the conductor, and the radio frequency power applied to the first electrode leaks through the radio frequency leakage line to an earth ground. In addition, an impedance adjusting circuit is provided on the radio frequency leakage line and controls an amount of the radio frequency power flowing through the radio frequency leakage line by adjusting an impedance.

### FIELD OF THE INVENTION

The present invention relates to a plasma processing apparatus for performing a plasma etching process, a film forming process or the like on a substrate to be processed, e.g., a semiconductor wafer, a substrate for use in an LCD (liquid crystal display) or the like.

### BACKGROUND OF THE INVENTION

Various processes such as a film forming process, an annealing process, an etching process, an oxidation/diffusion process and the like are performed in a manufacturing process of semiconductor devices. Most of these processes tend to be performed by using plasma generated by a radio frequency power. A parallel plate type plasma processing apparatus has been known as a plasma processing apparatus for performing such processes. In case of the parallel plate type plasma processing apparatus, a semiconductor wafer is mounted on a lower electrode serving as a mounting table, and a radio frequency power is applied to the lower electrode facing an upper electrode to thereby generate plasma therebetween. Therefore, various processes such as a film forming process or an etching process are performed by using the plasma.

FIG. 8 shows a plasma processing apparatus including a radio frequency power supply 63 connected to an upper electrode 61 via a matching circuit 62 and a radio frequency power supply 67, whose frequency is lower than the frequency of the radio frequency power supply 63, connected to a lower electrode 64 via a matching circuit 66 (see, Japanese Patent Laid-open Publication No. 2004-96066). The radio frequency power supply 63 connected to the upper electrode 61 is used to generate plasma and the radio frequency power supply 67 connected to the lower electrode 64 is used to provide a bias for attracting ions in plasma to a substrate W to be processed. The impedances of the matching circuits 62 and 66 are adjusted such that the radio frequency powers respectively supplied to the upper and lower electrodes 61 and 64 from the radio frequency power supplies 63 and 67 are not reflected, i.e., the radio frequency powers supplied from the respective radio frequency power supplies 63 and 67 are used for plasma without leaking.

This plasma processing apparatus is provided with a variable impedance unit 65 to adjust the impedance of the lower electrode 64. By adjusting the impedance of the lower electrode 64, a radio frequency current from the upper electrode 61 can flow through the lower electrode 64 or through a sidewall of a chamber 68 so that the plasma density distribution over the substrate W to be processed can be controlled. Therefore, the uniformity of plasma processing for the substrate W to be processed can be improved.

A recent trend toward miniaturization of electrical circuits requires the radio frequency power for biasing to attract ions to be controlled at a reduced level. Further, the radio frequency power for plasma generation as well as the radio frequency power for biasing needs to be controlled at a reduced level.

Currently, the radio frequency power used in plasma processing is controlled by the output of the radio frequency power supply. The radio frequency power used in plasma processing can be lowered by reducing the output of the radio frequency power supply. However, there is a limit to the reduction of the output of the radio frequency power supply. For example, in case of a radio frequency power supply with a low output for etching a polysilicon film, the output thereof can be controlled to be reduced only to 100 W in a guarantee range of a manufacturer.

Meanwhile, even when the variable impedance unit is provided to the lower electrode as in the plasma processing apparatus shown in FIG. 8, it is impossible to change the total amount of the radio frequency power used in plasma processing while the plasma density distribution over the substrate to be processed can be controlled.

### SUMMARY OF THE INVENTION

The present invention provides a plasma processing apparatus capable of controlling radio frequency power used in plasma processing at a reduced level.

In accordance with an aspect of the present invention, there is provided a plasma processing apparatus for performing a plasma processing on a substrate to be processed by generating plasma between a first electrode and a second electrode disposed to face each other in a processing chamber by applying a radio frequency power to the first electrode from a radio frequency power supply connected to the first electrode, the apparatus comprising: a dielectric body disposed near the first electrode; a conductor provided in the dielectric body; a radio frequency leakage line, which is connected to the conductor, for leaking the radio frequency power applied to the first electrode to an earth ground; and an impedance adjusting circuit, which is provided on the radio frequency leakage line, for controlling the radio frequency power flowing through the radio frequency leakage line by adjusting an impedance.

Preferably, the impedance adjusting circuit comprises at least one of a capacitance-variable capacitor and an inductance-variable coil to adjust the impedance.

The dielectric body may be an electrostatic chuck for attractively holding the substrate to be processed, and the conductor may be a heater embedded in the electrostatic chuck. In this case, the radio frequency leakage line also serves as a heater line connecting the heater with a heater power supply.

Alternatively, the dielectric body may be an electrostatic chuck for attractively holding the substrate to be processed and the conductor may be an internal electrode embedded in the electrostatic chuck. In this case, the radio frequency leakage line also serves as an electrode line connecting the internal electrode with a DC power supply.

The plasma processing apparatus may further comprise another radio frequency power supply, which is connected to the second electrode, for generating plasma. In this case, the radio frequency power supply connected to the first electrode has a lower frequency than that of the radio frequency power supply connected to the second electrode and provides a bias for attracting ions in plasma to the substrate to be processed.

The plasma processing apparatus may further comprise an ampere meter for measuring a current flowing through the radio frequency leakage line.

conventionally, it is a common knowledge that the radio frequency power supplied from the radio frequency power supply in the plasma processing apparatus is used for plasma without leaking. However, in accordance with the present invention, by purposely leaking the radio frequency power to the earth ground against the common knowledge, the radio frequency power used in plasma processing can be controlled to be at a reduced level. Accordingly, a plasma processing, e.g., by using radio frequency power below the guaranteed level of the radio frequency power supply can be realized.

### BRIEF DESCRIPTION OF THE DRAWINGS

The objects and features of the present invention will become apparent from the following description of preferred embodiments given in conjunction with the accompanying drawings, in which:

FIG. 1 shows a schematic configuration of a plasma processing apparatus in accordance with the preferred embodiment of the present invention;

FIG. 2 shows a detailed view of a heater line system and an electrostatic chuck electrode line system of the plasma processing apparatus;

FIG. 3 is a circuit diagram of an impedance adjusting circuit;

FIG. 4 shows another example of the heater line system;

FIG. 5 is a plan view showing a heater pattern;

FIG. 6 shows another example of the electrostatic chuck electrode line system;

FIGS. 7A to 7G are circuit diagrams of other impedance adjusting circuits; and

FIG. 8 shows a schematic configuration of a conventional plasma processing apparatus.

### DETAILED DESCRIPTION OF THE EMBODIMENTS

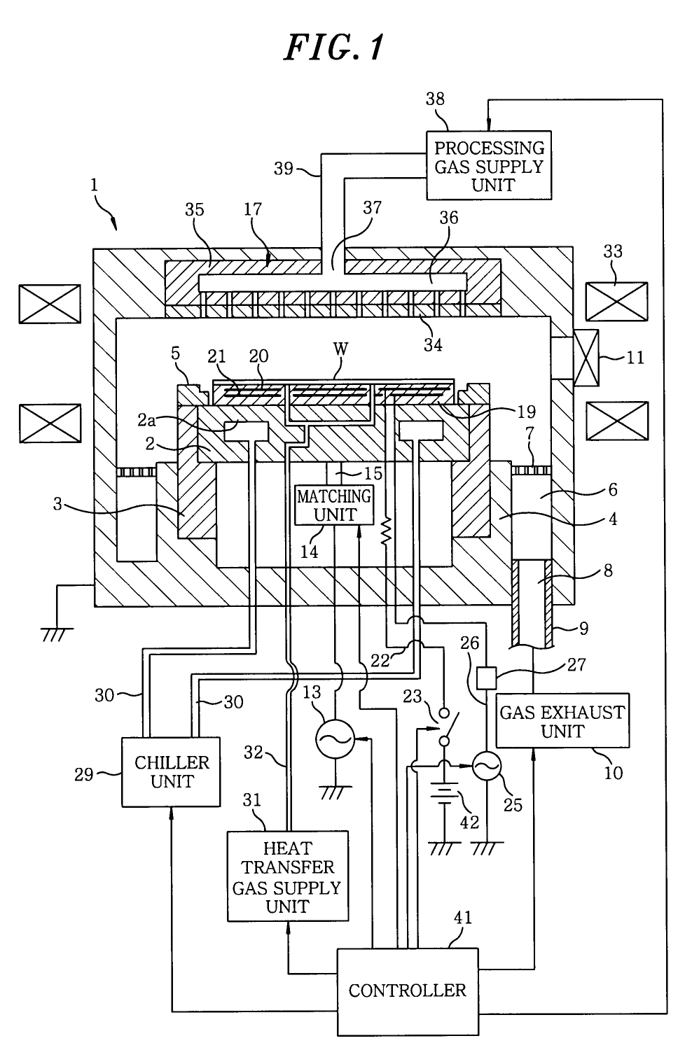

Hereinafter, a plasma processing apparatus in accordance with an embodiment of the present invention will be described with reference to the accompanying drawings. FIG. 1 shows an entire schematic configuration of a plasma processing apparatus (etching apparatus). In FIG. 1, reference numeral 1 indicates a cylindrical chamber made of aluminum, stainless steel or the like which can be airtightly sealed. The chamber 1 is frame grounded.

A circular plate-shaped susceptor 2 for mounting thereon a substrate to be processed, e.g., a semiconductor wafer W, is provided in the chamber 1. The susceptor 2 is made of a conductive material such as aluminum and also serves as a lower electrode (first electrode). The susceptor 2 is supported by a cylindrical support portion 3 made of an insulating material such as ceramic or the like. The cylindrical support portion 3 is supported by a cylindrical supporting member 4 of the chamber 1. A focus ring 5 made of quartz or the like is disposed on a top surface of the cylindrical support portion 3 to surround a top surface of the susceptor 2 in a ring shape.

An annular gas exhaust passageway 6 is formed between the sidewall of the chamber 1 and the cylindrical support portion 3. An annular baffle plate 7 is provided at the entrance or in the middle of the gas exhaust passageway 6. A gas exhaust port 8 is provided at a bottom portion of the gas exhaust passageway 6. A gas exhaust unit 10 is connected to the gas exhaust port 8 via a gas exhaust line 9. The gas exhaust unit 10 has a vacuum pump and reduces the pressure of a processing space in the chamber 1 to a predetermined vacuum level. A gate valve 11 is provided at the sidewall of the chamber 1 to open and close a loading/unloading port for the semiconductor wafer W.

A radio frequency power supply 13 for generating plasma is electrically connected to the susceptor 2 via a matching unit 14 and a power supply rod 15. The radio frequency power supply 13 applies a predetermined radio frequency power to the susceptor 2, i.e. the lower electrode. A shower head 17 serving as an upper electrode (second electrode) is provided at a ceiling portion of the chamber 1.

An electrostatic chuck 19 for holding the semiconductor wafer W by an electrostatic attraction force is installed on the top surface of the susceptor 2. The electrostatic chuck 19 is made of a dielectric material such as alumina. An electrostatic chuck electrode 20 and a heater 21, which are conductors, are embedded in the electrostatic chuck 19. The electrostatic chuck electrode 20 is formed of a conductive film made of copper, tungsten or the like, while the heater 21 is formed of a conductive film made of niobium (Nb) or the like. A DC power supply 42 is electrically connected to the electrostatic chuck electrode 20 via a switch 23. The semiconductor wafer W is attracted and held to the electrostatic chuck 19 by Coulomb force generated by a DC voltage applied to the electrostatic chuck electrode 20 from the DC power supply 42.

The heater 21 is connected to an AC heater power supply 25 via a heater line 26. The heater line 26 also functions as a radio frequency leakage line and is provided with an impedance adjusting circuit 27. The semiconductor wafer W is heated by the heater 21 if an AC voltage is applied to the heater 21 from the heater power supply 25 via the heater line 26. The heater line 26 serving as a radio frequency leakage line and the impedance adjusting circuit 27 will be described later.

The electrostatic chuck 19 is fabricated, for example, as follows. First, a lower dielectric layer is formed by spraying alumina on the top surface of the susceptor 2. The heater 21 is formed by spraying a conductive material on a top surface of the lower dielectric layer. Then, an intermediate dielectric layer is formed by spraying alumina on a top surface of the heater 21. The electrostatic chuck electrode 20 is then formed by spraying a conductive material such as tungsten or the like on a top surface of the intermediate dielectric layer. By spraying alumina on a top surface of the electrostatic chuck electrode 20, an upper dielectric layer is finally formed.

A coolant path 2a formed in, e.g., a ring shape extending circumferentially is provided inside the susceptor 2. A coolant of a specific temperature is supplied into the coolant path 2a from a chiller unit 29 via a line 30 to be circulated along the coolant path 2a. The processing temperature of the semiconductor wafer W on the electrostatic chuck 19 is controlled by the temperatures of the heater 21 and the coolant. Further, a heat transfer gas, e.g., He gas, from a heat transfer gas supply unit 31 is supplied between the top surface of the electrostatic chuck 19 and a rear surface of the semiconductor wafer W via a gas supply line 32 in order to improve thermal conductivity between the electrostatic chuck 19 and the semiconductor wafer W.

The shower head 17 at the ceiling portion of the chamber 1 has an electrode plate 34 having a number of gas passing holes in a lower surface thereof and an electrode supporting body 35 for supporting the electrode plate 34 such that the electrode 34 can be attached thereto or detached therefrom. A buffer chamber 36 is formed inside the electrode supporting body 35 and a processing gas supply unit 38 is connected to a gas inlet port 37 of the buffer chamber 36 via a gas supply line 39.

The shower head 17 and the susceptor 2 are disposed to face each other in parallel and the shower head 17 is grounded. The shower head 17 and the susceptor 2 serve as a pair of electrodes, i.e., the upper and lower electrodes. A radio frequency electric field in the vertical direction is formed between the shower head 17 and the susceptor 2 by the radio frequency power supply. High-density plasma is formed near the surface of the susceptor 2 by a radio frequency discharge.

Disposed around the chamber 1 is an annular ring magnet 33 arranged concentrically with the chamber 1. The ring magnet 33 generates a magnetic field in the processing space between the susceptor 2 and the shower head 17. The ring magnet 33 can be rotated around the chamber 1 by a rotation mechanism.

A controller 41 controls an operation of each unit inside the plasma processing apparatus such as a gas exhaust unit 10, the radio frequency power supply 13, the switch 23 for the electrostatic chuck 19, the heater power supply 25, the chiller unit 29, the heat transfer gas supply unit 31 and the processing gas supply unit 38. Further, the controller 41 is connected to a host computer (not shown).

In this plasma processing apparatus, for etching, the gate valve 11 is first opened, and the semiconductor wafer W as an object to be processed is loaded into the chamber 1 and mounted on the electrostatic chuck 19. The semiconductor wafer W is held on the electrostatic chuck 19 by applying a DC voltage (HV) to the electrostatic chuck electrode 20 from the DC power supply 42. A predetermined processing gas (etching gas) is introduced into the chamber 1 from the processing gas supply unit 38 and the inner pressure of the chamber 1 is set at a predetermined level by the gas exhaust unit 10. Further, radio frequency power, e.g., whose frequency is 40 MHz, is supplied to the susceptor 2 from the radio frequency power supply 13. By the radio frequency power applied to the susceptor 2 serving as the lower electrode, a radio frequency electric field is formed between the shower head 17 serving as the upper electrode and the susceptor 2 serving as the lower electrode, thereby generating plasma. The semiconductor wafer W is etched by radicals and/or ions in plasma. The ring magnet 33 confines the generated plasma in the magnetic field, thereby increasing a density of the plasma. If a predetermined plasma etching process is completed, the radio frequency power supply 13 stops supplying radio frequency power. Then, the semiconductor wafer W is unloaded from the chamber 1 in the reverse order of the loading sequence described above.

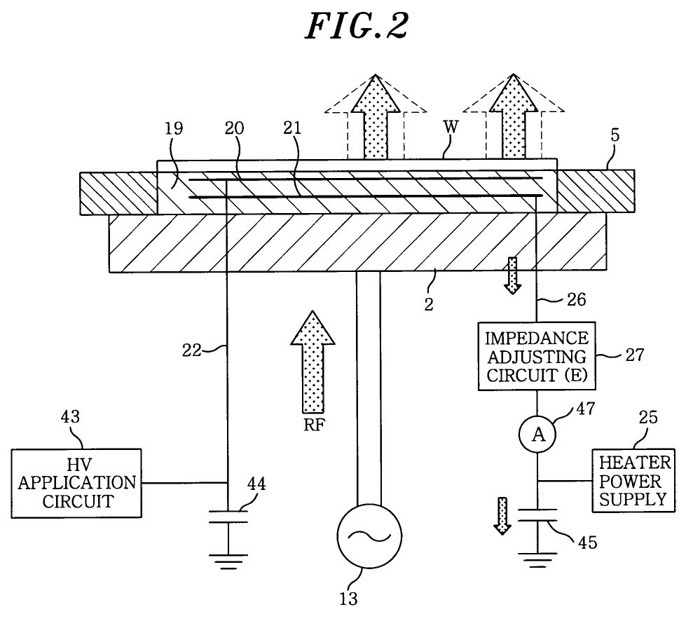

Hereinafter, the features of the plasma processing apparatus of the present embodiment will be described. FIG. 2 shows a detailed view of a heater line system and an electrostatic chuck electrode line system. As described above, the electrostatic chuck electrode 20 and the heater 21, which are conductors, are embedded in the electrostatic chuck 19. A DC voltage (HV) application circuit 43 with a DC power supply is connected to the electrostatic chuck electrode 20 via an electrostatic chuck electrode line 22. The electrostatic chuck electrode line 22 is connected to the earth ground via a capacitor 44. The capacitor 44 prevents a current supplied from the DC voltage application circuit 43 to the electrostatic chuck electrode 20 from flowing to the earth ground.

The heater power supply 25 is connected to the heater 21 via the heater line 26. The heater line 26 is grounded to the earth via a capacitor 45. The capacitor 45 prevents a current supplied from the heater power supply 25 to the heater 21 from flowing to the earth ground.

The heater line 26 functions as a radio frequency leakage line which allows radio frequency power (current) supplied to the susceptor 2 to flow to the earth ground.

The heater line 26 is basically designed to afford a high current so that a radio frequency current, e.g., greater than 10 A, can flow therethrough without causing a problem. The heater line 26 between the heater 21 and the heater power supply 25 is provided with the impedance adjusting circuit 27 for adjusting the impedance against the radio frequency current supplied to the susceptor 2. The impedance adjusting circuit 27 controls the radio frequency current flowing through the heater line 26. The radio frequency current flowing through the heater line 26 is measured by an ampere meter 47.

FIG. 3 shows an example of the impedance adjusting circuit. The impedance adjusting circuit 27 includes a fixed coil 48 and a variable capacitor 49 which are connected in parallel between the heater line 26 and the earth ground. The fixed coil 48 has a constant inductance. The capacitance of the variable capacitor 49 is changed by adjusting a dial 50 directly connected to the variable capacitor 49. An operator may adjust the dial 50 while monitoring the ampere meter 47 such that the current reaches a predetermined value. Otherwise, the controller 41 (see, FIG. 1) can feedback-control the dial 50 by using the current measured by the ampere meter 47 as a feedback signal so that the current reaches a predetermined value. Further, the fixed coil 48 can be replaced by a variable coil whose inductance can be adjusted and the variable capacitor 49 can be replaced by a fixed capacitor having a constant capacitance.

As shown in FIG. 2, if radio frequency power from the radio frequency power supply 13 is applied to the susceptor 2, the radio frequency power indicated by the dashed line is generally exerted on plasma. However, in the present embodiment, by connecting the heater line 26 to the heater 21 embedded in the electrostatic chuck 19, the radio frequency power applied to the susceptor 2 is purposely leaked to the heater line 26. Therefore, the radio frequency power applied to the susceptor 2 flows in two channels, i.e., one channel to the plasma and the other channel to the earth ground via the heater line 26. The radio frequency power used in plasma processing is reduced by the radio frequency power leaking to the earth ground via the heater line 26.

Further, the radio frequency current flowing through the heater line 26 is controlled by the impedance adjusting circuit 27. If the impedance of the impedance adjusting circuit 27 is set to be high, for example, equal to or greater than 500Ω, it is difficult for the radio frequency current to flow into the heater line 26. On the contrary, if the impedance is set to be low, the radio frequency current can flow easily through the heater line 26. By controlling the leakage amount of the radio frequency current to the heater line 26, the radio frequency power used in plasma processing can be controlled, accordingly.

The radio frequency power used in plasma processing can be controlled by the output of the radio frequency power supply 13. However, there is a limit to the reduction of the output of the radio frequency power supply 13. By purposely leaking the radio frequency power used in plasma processing to the heater line 26 while controlling the leakage amount of the radio frequency current flowing through the heater line 26, the radio frequency power used in plasma processing can be controlled to a level below the output of the radio frequency power supply 13. In other words, plasma processing can be performed under the minimum output of the radio frequency power supply in a guarantee range of a manufacturer thereof. For example, if the output of the radio frequency power supply is 100 W, the radio frequency power for plasma can be controlled under 100 W by leaking the radio frequency power to the heater line 26.

Further, since the radio frequency current introduced to the heater line 26 flows through the capacitor 45 to the earth ground, the heater power supply 25 is not damaged thereby. The heater power supply 25 has a filter circuit to prevent the radio frequency current from flowing to the heater power supply 25.

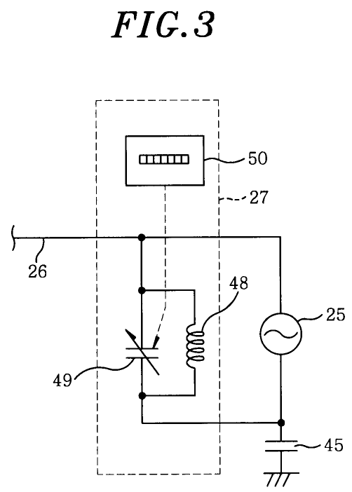

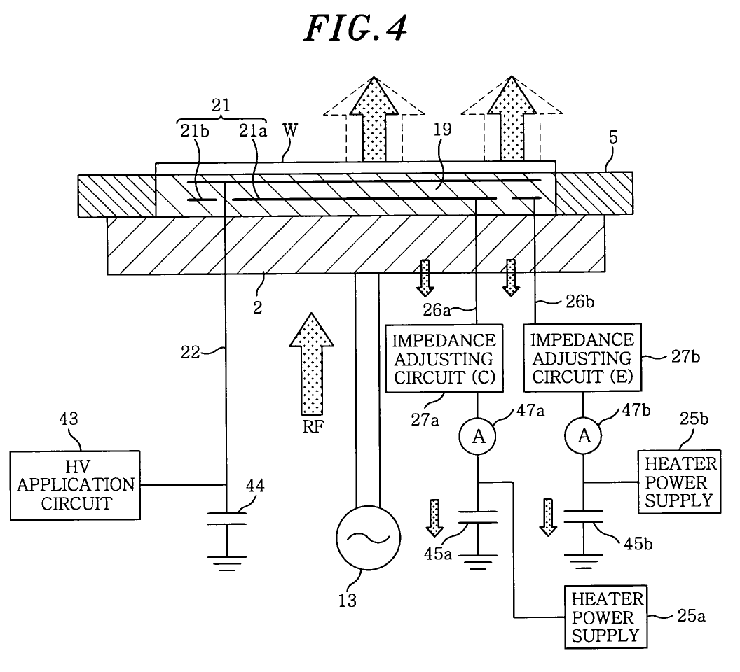

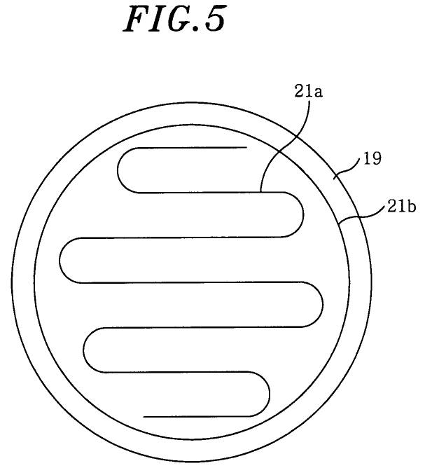

FIGS. 4 and 5 show another example of the heater line system. As shown in FIG. 5, the heater 21 embedded in the electrostatic chuck 19 includes a central region 21a corresponding to a central portion of the semiconductor wafer W and a peripheral region 21b corresponding to a peripheral portion of the semiconductor wafer W. As shown in FIG. 4, heater lines 26a and 26b are respectively connected to the central and peripheral regions 21a and 21b of the heater 21. Heater power supplies 25a and 25b are respectively connected to the heater lines 26a and 26b of the two line system. Further, the heater lines 26a and 26b of the two line system are provided with impedance adjusting circuits 27a and 27b, respectively. The circuit configuration of the impedance adjusting circuits 27a and 27b are the same as that of the impedance adjusting circuit 27 shown in FIG. 3. The heater lines 26a and 26b are grounded to the earth via respective capacitors 45a and 45b.

As the semiconductor wafer W has a greater diameter of 200 mm, 300 mm, 450 mm and so on, it is difficult to perform the plasma processing on the semiconductor wafer W uniformly. This is because the plasma density becomes denser in the central portion of the semiconductor wafer W than the peripheral portion thereof. In accordance with the present embodiment, the heater lines 26a and 26b are respectively connected to the central and peripheral regions 21a and 21b of the heater 21 so that the radio frequency currents from the central and peripheral regions 21a and 21b of the heater 21 can be individually controlled. Therefore, the uniformity of the plasma processing can be improved.

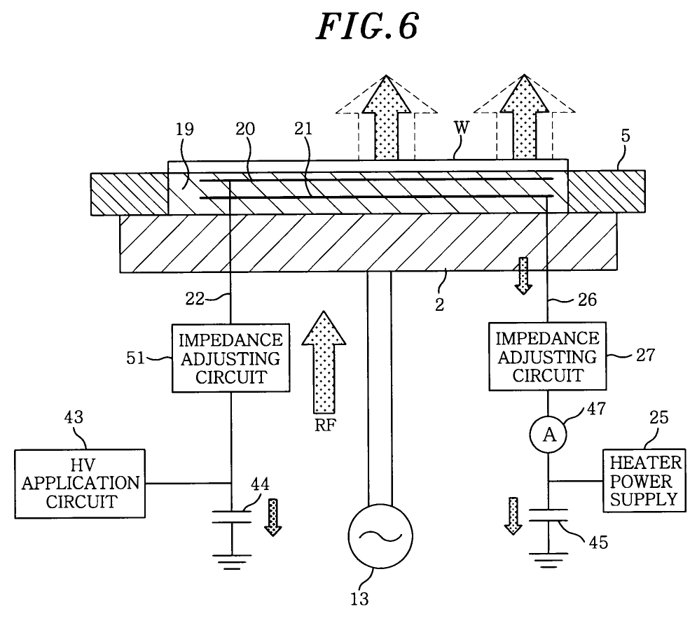

FIG. 6 shows another example of the electrostatic chuck electrode line system. The electrostatic chuck electrode line in this example is provided with an impedance adjusting circuit 51. The impedance adjusting circuit 51 controls the radio frequency current flowing to the earth via the electrostatic chuck electrode line 22. The radio frequency power used in plasma processing can also be controlled by providing the electrostatic chuck electrode line 22 with the impedance adjusting circuit 51 as in this example. However, it should be noted that since the impedance of the electrostatic chuck electrode line 22 is high, it is difficult for the radio frequency current to flow through the electrostatic chuck electrode line 22 compared with the heater line 26.

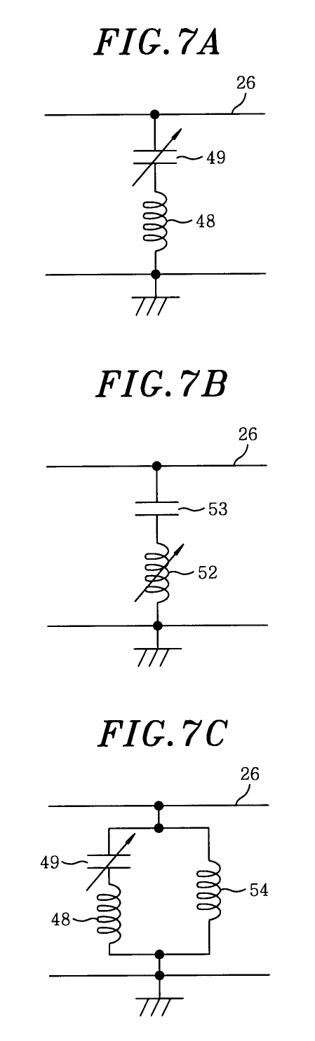

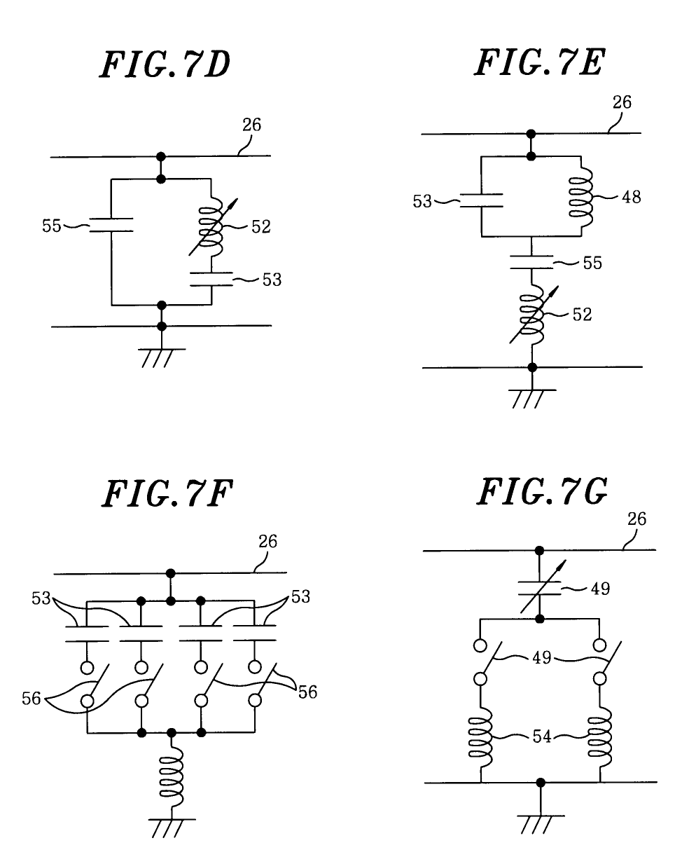

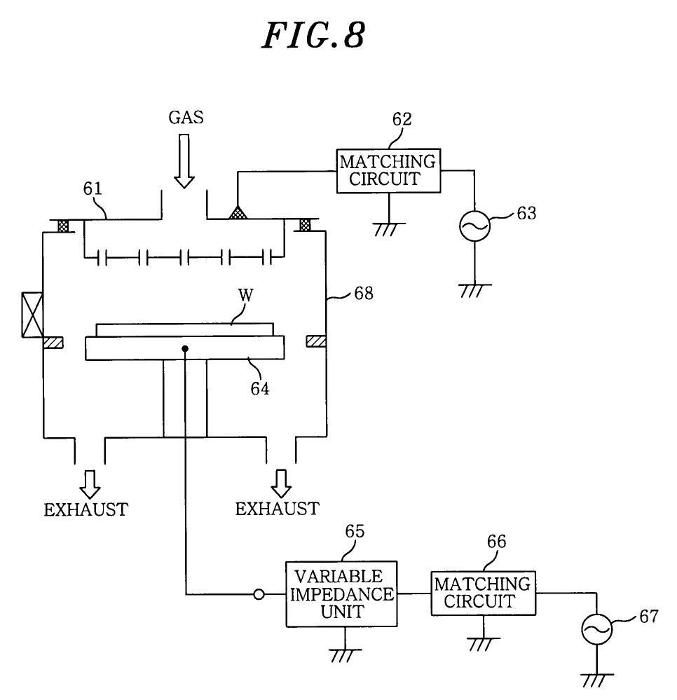

FIGS. 7A to 7G show other examples of the impedance adjusting circuit 27. Although, in the impedance adjusting circuit 27 shown in FIG. 3, the fixed coil 48 and the variable capacitor 49 are connected in parallel between the heater line 26 and the earth ground, the impedance adjusting circuit 27 is not limited thereto. The impedance adjusting circuit 27 may be configured as in FIGS. 7A to 7G. FIG. 7A is a circuit where the fixed coil 48 and the variable capacitor 49 are connected in series with each other. FIG. 7B shows a circuit where an inductance-variable coil 52 and a fixed capacitor 53 are connected in series with each other. The variable capacitor 49 may be used instead of the fixed capacitor 53. FIG. 7C shows a circuit where the variable capacitor 49 and the fixed coil 48 are connected in series, and the series circuit of the variable capacitor 49 and the fixed coil 48 is connected in parallel with a fixed coil 54. In this way, series resonance between the variable capacitor 49 and the fixed coil 48 can result in the minimum impedance and parallel resonance between the variable capacitor 49 and the fixed coil 48 and the fixed coil 54 can result in the maximum impedance. FIG. 7D shows a circuit where a series circuit of the variable coil 52 and the fixed capacitor 53 is connected in parallel with a fixed capacitor 55. FIG. 7E is a circuit where a parallel circuit of the fixed capacitor 53 and the fixed coil 48, the fixed capacitor 55 and the variable coil 52 are sequentially connected in series in that order. FIG. 7F shows a circuit where the capacitance can be adjusted by controlling ON/OFF states of switches 56 respectively connected in series with a plurality of the fixed capacitors 53. FIG. 7G shows a circuit where the inductance can be adjusted by controlling ON/OFF states of the switches 56 respectively connected in series with a plurality of the fixed coils 54. In addition, by connecting the variable capacitor 49, micro adjustment can be achieved by using the variable capacitor 49 and macro adjustment can be achieved by changing the inductance.

Although the plasma processing apparatus in accordance with the embodiments of the present invention has been described above, the present invention is not limited to the above embodiments and may be modified in the following way without departing the scope of the present invention.

Although, in the plasma processing apparatus of the embodiment as shown in FIG. 1, radio frequency power is applied only to the susceptor 2 serving as the lower electrode, radio frequency power having a different frequency may also be applied to the shower head 17 serving as the upper electrode from a radio frequency power supply via a matching circuit. Besides, the first and second radio frequency powers of different frequencies may be dually applied to the susceptor 2. Here, the radio frequency power of a higher frequency (HF power) is used to generate plasma and the radio frequency power of a lower frequency (LF power) is used to provide a bias for attracting ions. In case of the plasma processing apparatus where radio frequency powers are respectively applied to the upper and lower electrodes, it is preferable that HF power is applied to the upper electrode and LF power is applied to the lower electrode. A recent trend toward miniaturization of electrical circuits requires the radio frequency power used to provide a bias for attracting ions to be controlled at a lower level. The present invention is effective in controlling radio frequency power used to provide a bias at a reduced level. Although the plasma processing apparatus of the embodiments described above is provided with the ring magnet 33, the ring magnet 33 may be omitted.

Further, by installing a dielectric body and a conductor at a shower head to which HF power is applied, the HF power may flow to the earth ground. In this case, a plasma density distribution over a semiconductor wafer can be uniform by dividing the conductor into a central region and a peripheral region and controlling radio frequency currents from the respective regions.

The present invention may also be applied to other plasma processing apparatuses such as a plasma CVD apparatus, a plasma oxidation apparatus, a plasma nitriding apparatus, a sputtering apparatus and so on.

Further, the substrate to be processed in the present invention is not limited to a semiconductor wafer and a substrate for use in an LCD (Liquid Crystal Display), a photomask, a CD substrate, a print substrate and the like may be used.

While the invention has been shown and described with respect to the preferred embodiments, it will be understood by those skilled in the art that various changes and modifications may be made without departing from the scope of the invention as defined in the following claims.

What is claimed is:

1. A plasma processing apparatus for performing a plasma processing on a substrate to be processed by generating plasma between a first electrode and a second electrode disposed to face each other in a processing chamber by applying a radio frequency power to the first electrode from a radio frequency power supply connected to the first electrode, the apparatus comprising:
a dielectric body disposed near the first electrode;
a conductor provided in the dielectric body;
a radio frequency leakage line, which is connected to the conductor, for leaking the radio frequency power applied to the first electrode to an earth ground; and
an impedance adjusting circuit, which is provided on the radio frequency leakage line, for controlling the radio frequency power flowing through the radio frequency leakage line by adjusting an impedance.

2. The plasma processing apparatus of claim 1, wherein the impedance adjusting circuit comprises at least one of a capacitance-variable capacitor and an inductance-variable coil to adjust the impedance.

3. The plasma processing apparatus of claim 1, wherein the dielectric body is an electrostatic chuck for attractively holding the substrate to be processed, the conductor is a heater embedded in the electrostatic chuck and the radio frequency leakage line also serves as a heater line connecting the heater with a heater power supply.

4. The plasma processing apparatus of claim 2, wherein the dielectric body is an electrostatic chuck for attractively holding the substrate to be processed, the conductor is a heater embedded in the electrostatic chuck and the radio frequency leakage line also serves as a heater line connecting the heater with a heater power supply.

5. The plasma processing apparatus of claim 1, wherein the dielectric body is an electrostatic chuck for attractively holding the substrate to be processed, the conductor is an internal electrode embedded in the electrostatic chuck and the radio frequency leakage line also serves as an electrode line connecting the internal electrode with a DC power supply.

6. The plasma processing apparatus of claim 2, wherein the dielectric body is an electrostatic chuck for attractively holding the substrate to be processed, the conductor is an internal electrode embedded in the electrostatic chuck and the radio frequency leakage line also serves as an electrode line connecting the internal electrode with a DC power supply.

7. The plasma processing apparatus of claim 1, further comprising:
another radio frequency power supply, which is connected to the second electrode, for generating plasma,
wherein the radio frequency power supply connected to the first electrode has a lower frequency than that of the radio frequency power supply connected to the second electrode and provides a bias for attracting ions in plasma to the substrate to be processed.

8. The plasma processing apparatus of claim 1, further comprising an ampere meter for measuring a current flowing through the radio frequency leakage line.
